(19) United States
(12) Patent Application Publication
(10) Pub. No.: US 2010/0025098 A1
(43) Pub. Date: Feb. 4, 2010

(54) WIRELESS COMMUNICATION DEVICE WITH IMPROVED SENSITIVITY OF ANTENNA THEREOF

(75) Inventor: Chun-Chieh Wang, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: Chi Mei Communication Systems, Inc., Tu-Cheng City (TW)

(21) Appl. No.: 12/333,438

(22) Filed: Dec. 12, 2008

(30) Foreign Application Priority Data
Jul. 31, 2008 (CN) 200810303276.1

(51) Int. Cl. H05K 1/00; H05K 1/11

(52) U.S. Cl. 174/262; 174/250

(57) ABSTRACT

A wireless communication device includes a circuit board, a metallic plate, and at least one conductive member. The circuit board includes a grounding point. The metallic plate is positioned on the circuit board. The at least one conductive member is sandwiched between the circuit board and the metallic plate, and is configured for electrically connecting the metallic plate to the grounding point of the circuit board.

### BACKGROUND

1. Technical Field

The present disclosure relates to a wireless communication device with an improved sensitivity of an antenna thereof.

2. Description of the Related Art

Wireless communication devices use antennas to transmit and receive compatible radio-frequency signals. Cell phones, for example, include antennas that are used to handle radio-frequency communications with cellular base stations or satellites. In these wireless communication devices, key assemblies are provided for operations of the wireless communication devices. The key assembly includes a plurality of keys for a user to input information and a plurality of key pads corresponding to the keys between the keys and a circuit board of the wireless communication device. The circuit board may include a plurality of key contacts right below the key pads.

Generally, a metallic plate is sandwiched between a circuit board in the device and the key assembly to enhance a mechanical strength of the device. However, the metallic plate may cover a feeding point of the antenna, decreasing the sensitivity of the antenna.

What is needed, therefore, is to provide a wireless communication device, in which the sensitivity of the antenna is improved.

### BRIEF DESCRIPTION OF THE DRAWINGS

FIG. 1 is a schematic view of a wireless communication device according to a first exemplary embodiment of the present disclosure.

FIG. 2 is a partially disassembled view of the wireless communication device of FIG. 1.

FIG. 3 is a partially disassembled view of a wireless communication device according to a second exemplary embodiment of the present disclosure.

FIG. 4 is a partially disassembled view of a wireless communication device according to a third exemplary embodiment of the present disclosure.

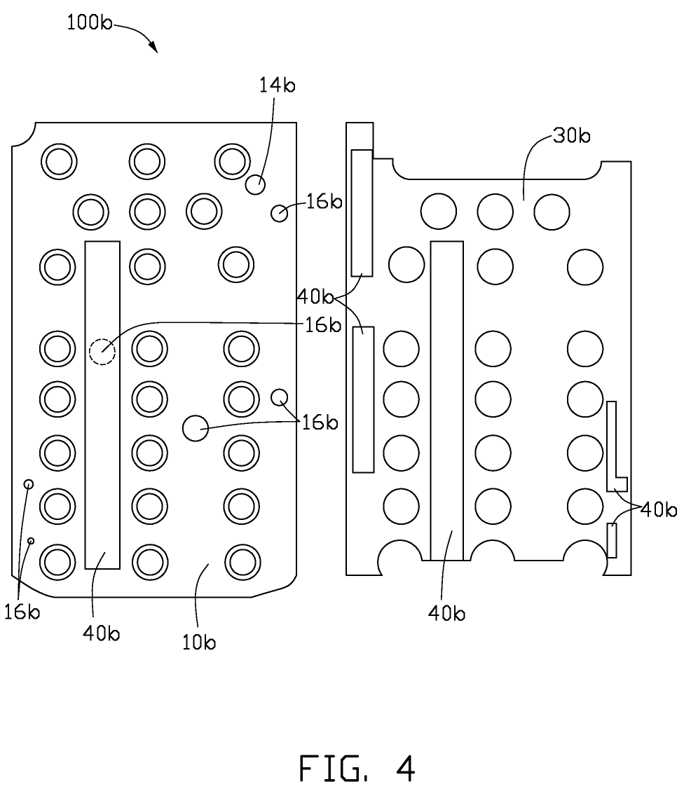

### DETAILED DESCRIPTION OF THE EMBODIMENTS

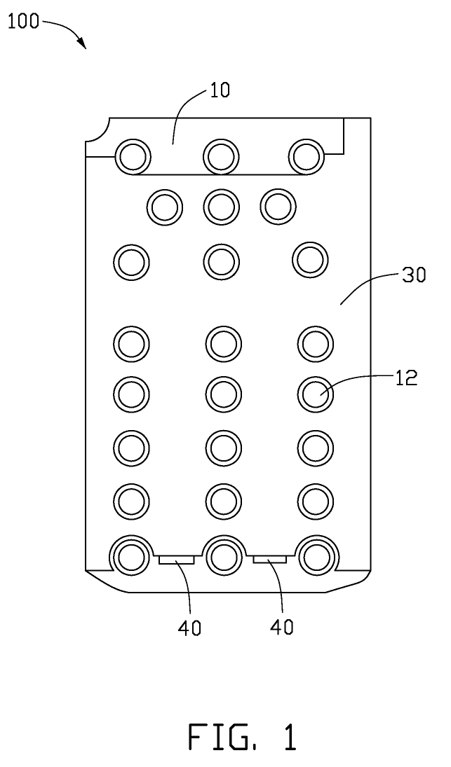

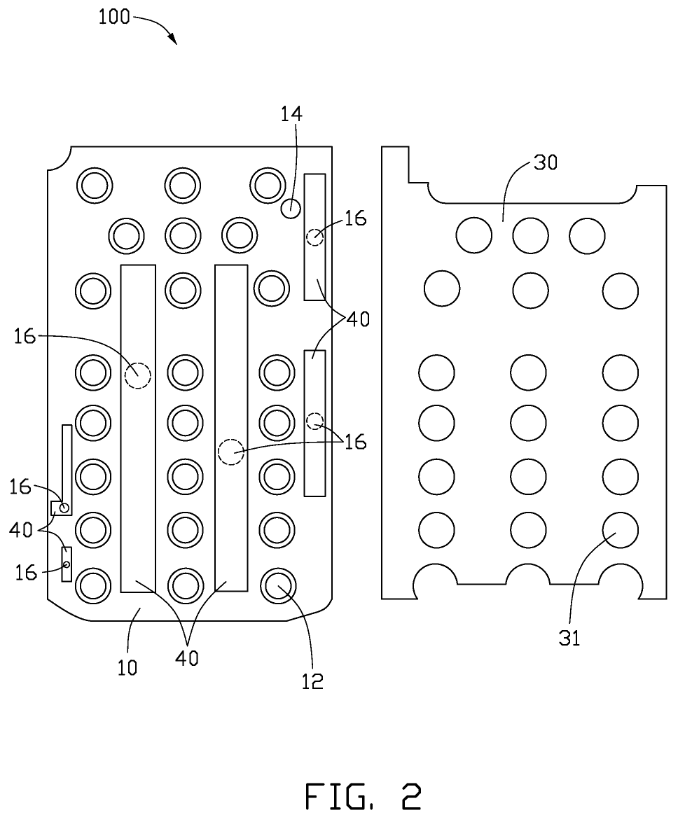

Referring to FIGS. 1 and 2, a wireless communication device 100 according to a first embodiment of the present disclosure includes a circuit board 10, a metallic plate 30 and a plurality of conductive members 40. The metallic plate 30 is positioned on the surface of circuit board 10 with a feeding point 14. The feeding point 14 may be coupled to an antenna (not shown) of the wireless communication device 100. The circuit board 10 includes a plurality of key contacts 12 formed on the surface of the circuit board 10 facing the metallic plate 30. An arrangement of the key contacts 12 may correspond to that of keys (not shown) of the device 100. The keys may be used for a user to input information to the device 100.

The conductive members 40 are attached to the surface of the circuit board 10 facing the metallic plate 30. In the illustrated embodiment, the conductive members 40 are conductive tapes, and are adhered to the surface of the circuit board 10 facing the metallic plate 30. A plurality of grounding points 16 are formed on the circuit board 10, electrically connected to the conductive members 40 respectively. The conductive members 40 are insulated from the key contacts 12 and the feeding point 14.

The metallic plate 30 defines a plurality of through holes 31 corresponding to the key contacts 12 so that the key contacts 12 may be exposed from the metallic plate 30. When the metallic plate 30 is positioned on the circuit board 10, the conductive members 40 contact the metallic plate 30, thereby electrically connecting the metallic plate 30 to the grounding points 16 of the circuit board 10. In this way, a grounding area between the circuit board 10 and the metallic plate 30 is increased to enhance an ability for transmitting noise signals generated by the metallic plate 30 to the grounding points 16. Therefore, the sensitivity of the antenna can be improved.

Referring to FIG. 2, a wireless communication device 100a according to a second exemplary embodiment of the present disclosure is shown. Differences between the wireless communication device 100a and the wireless communication device 100 are that the conductive members 40a are electrically attached to the surface of the metallic plate 30a facing the circuit board 10a. When the metallic plate 30a is positioned on the circuit board 10a, the conductive members 40a contacts the grounding points 16a, thereby electrically connecting the metallic plate 30a to the grounding points 16a of the circuit board 10a.

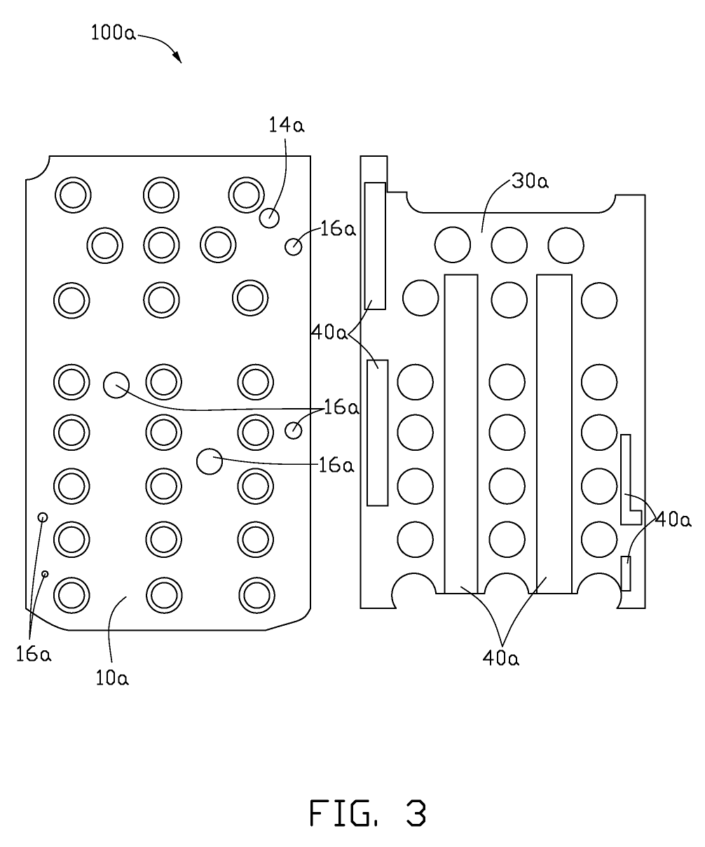

Referring to FIG. 3, a wireless communication device 100b according to a third exemplary embodiment is shown. Differences between the wireless communication device 100b and the wireless communication device 100 are that some of the conductive members 40b are electrically attached to the surface of the circuit board 10b facing the metallic plate 30b and the other conductive members 40b are electrically attached to the surface of the metallic plate 30b facing the circuit board 10b. When the metallic plate 30b is positioned on the circuit board 10b, the conductive members 40b contacts the metallic plate 30b and the circuit board 10b, thereby electrically connecting the metallic plate 30b to the grounding points 16b of the circuit board 10b.

In summary, the wireless communication device use conductive members to increase a grounding area between the circuit board and the metallic plate to enhance an ability for transmitting noise signals generating in the metallic plate to the grounding point. Therefore, the sensitivity of the antenna can be improved.

It is to be understood, however, that even though a plurality of characteristics and advantages of the present disclosure have been set forth in the foregoing description, together with details of the structure and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A wireless communication device comprising:
a circuit board comprising a grounding point;
a metallic plate being positioned on the circuit board; and
at least one conductive member being sandwiched between the circuit board and the metallic plate, and being configured for electrically connecting the metallic plate to the grounding point of the circuit board.

2. The wireless communication device as claimed in claim 1, wherein the at least one conductive member is electrically attached to the surface of the circuit board facing the metallic plate.

3. The wireless communication device as claimed in claim 1, wherein the at least one conductive member is electrically attached to the surface of the metallic plate facing the circuit board.

4. The wireless communication device as claimed in claim 1, comprising a plurality of conductive members being electrically attached to the surface of the circuit board facing the metallic plate and the surface of the metallic plate facing the circuit board.

5. The wireless communication device as claimed in claim 1, wherein the at least one conductive member is a conductive tape.

6. The wireless communication device as claimed in claim 1, wherein the circuit board further comprises a plurality of key contacts; the metallic plate defines a plurality of through holes corresponding to the plurality of key contacts.

7. A wireless communication device comprising:
a circuit board comprising a grounding point and a feeding point;
a metallic plate being positioned on the circuit board and covering the feeding point; and
at least one conductive member being sandwiched between the circuit board and the metallic plate, and being configured for electrically connecting the metallic plate to the grounding point of the circuit board.

8. The wireless communication device as claimed in claim 7, wherein the at least one conductive member is electrically attached to the surface of the circuit board facing the metallic plate.

9. The wireless communication device as claimed in claim 7, wherein the at least one conductive member is electrically attached to the surface of the metallic plate facing the circuit board.

10. The wireless communication device as claimed in claim 7, comprising a plurality of conductive members being electrically attached to the surface of the circuit board facing the metallic plate and the surface of the metallic plate facing the circuit board.

11. The wireless communication device as claimed in claim 7, wherein the at least one conductive member is a conductive tape.

12. The wireless communication device as claimed in claim 7, wherein the circuit board further comprises a plurality of key contacts; the metallic plate defines a plurality of through holes corresponding to the plurality of key contacts.
